(19) United States
(12) Patent Application Publication
(10) Pub. No.: US 2012/0121983 A1
(43) Pub. Date: May 17, 2012

(54) Lithium Deposited Anode for a Lithium Second Battery and Its Manufacturing Method

(75) Inventors: Woo-Young Yoon, Seoul (KR); Heon Lee, Seoul (KR); Dae-Gun Jin, Gyeonggi-do (KR)

(73) Assignee: KOREA UNIVERSITY RESEARCH AND BUSINESS FOUNDATION, Seoul (KR)

(21) Appl. No.: 13/084,236

(22) Filed: Apr. 11, 2011

(30) Foreign Application Priority Data
Nov. 17, 2010 (KR) 10-2010-0114321

(51) Int. Cl. H01M 4/58; B05D 5/12; G03F 7/20; H01M 4/1395

(52) U.S. Cl. 429/220; 429/231.95; 427/123; 427/125; 430/314; 429/223

(57) ABSTRACT

The present invention relates to a lithium deposited anode for a lithium secondary battery and a method for preparing the same, and more particularly, to an anode suitable for a lithium secondary battery which limits dendrite growth only inside the concave portion of the silicon substrate during a battery is charged/discharged by depositing lithium as an active material only on the deeply caved concave portion of an anode current collector of which a micro-size patterned silicon substrate has conductivity provided by a metal, and its manufacturing method.

### TECHNICAL FIELD

The present invention relates to a lithium deposited anode for a lithium secondary battery and a method for preparing the same, and more particularly, to an anode suitable for a lithium secondary battery which limits dendrite growth only inside the concave portion of the silicon substrate during a battery is charged/discharged by depositing lithium as an active material only on the deeply caved concave portion of an anode current collector of which a micro-size patterned silicon substrate has conductivity provided by a metal, and its manufacturing method.

### BACKGROUND

A great deal of development research is currently under way on secondary batteries used as a power source in response to demands for mobile wireless devices such as mobile phones, portable computers, and camcorders with lighter weight and greater capabilities. Examples of such secondary batteries are nickel cadmium batteries, nickel hydrogen batteries, nickel zinc batteries and lithium secondary batteries, etc. Among them, the lithium secondary battery has attracted attention since it may be rechargeable and have miniaturized large capacities, high operating voltages and high energy density per unit weight. A material which has high reversible potential by reversibly occluding and releasing lithium ions is used as a cathode material for the lithium secondary battery such as LiCoO₂, LiNiO₂ and LiMn₂O₄, etc.

A lithium metal has been proposed as an ideal anode material for the lithium secondary battery since it has the highest energy density per unit weight and −3.04V of low standard hydrogen potential. When lithium is used as an anode material of a lithium secondary battery, the theoretical capacity may be 3860 mAhg⁻¹ which is more than 100 times higher than that of the current commercial battery. However, dendrite grows on the surface of the lithium metal while being charged and may be precipitated out while being discharged in this case. Further, it may reach the opposite cathode through a separator during continuous charging•discharging processes, which may cause internal short and thus deteriorate battery capacity and charge•discharge efficiency. In addition, the precipitated dendrite rapidly increases reactivity due to increased surface area of the electrode, reacts with an electrolyte at the surface of the electrode, and forms a conductivity-lacked polymer membrane. The faster charging rate is and the larger inhomogeneity of the polymer membrane becomes, the more the dendrite growth is. Thus, battery resistance rapidly increases or particles isolated from the conductive network are present. These will finally hinder discharging process.

Carbon materials such as graphite, carbon and the like which may observe/release lithium ions have been introduced to replace lithium as an anode material due to the above-mentioned problems. When lithium itself is used as an anode material, maximum number of the charge•discharge cycle is only about dozens of times and it is far inferior in terms of total energy storage. However, a carbon material such as graphite, carbon and the like, which may greatly increase charge and discharge cycle, even though it has low 1-cycle capacity, does not cause internal short occurred due to dendrite because metal lithium is not participated out neither other additional problems associated with this internal short. Therefore, it may be used as a safe anode material for a secondary battery. However, the anode material such as graphite, carbon and the like has 372 mAhg⁻¹ of theoretical lithium storage capacity which is a very low capacity corresponding to 10% of lithium metal theoretical capacity and also degrades life cycle.

There is a demand for research on metallic or inter-metallic compound materials as an anode material in order to improve such problems. However, even though a metal active material including such metals has very high theoretical discharge capacity, it has drawbacks of rapid decrease in electrochemical reversibility and corresponding charge/discharge efficiency and charge/discharge capacity during electrochemical cycles. Therefore, there is a large demand for using lithium itself as an anode material and preventing dendrite growth on the surface of the lithium during charging process.

### DISCLOSURE

### Technical Problem

As a result of efforts of the inventors of the present invention to develop an anode for a lithium secondary battery of which the above-mentioned problems are solved, it has been completed by providing an anode in which lithium is used directly for a lithium secondary battery and dendrite growth is inhibited.

An aspect of the present invention is to provide an anode suitable for a lithium secondary battery which may replace the existing carbon anode and is prepared by forming micro-size concave-convex patterns on a silicon substrate of an anode current collector, providing conductivity with metal or impurity, and depositing lithium as an anode active material only on the deeply caved concave portion of the anode current collector to limit dendrite growth only inside the concave portion of the silicon substrate during a battery is charged/discharged, and its manufacturing method.

### Technical Solution

In order to achieve the object of the present invention, there is provided an anode for a lithium secondary battery comprising a concave-convex pattern-formed silicon anode current collector and lithium deposited on the concave portion of the silicon anode current collector as an anode active material.

According to an embodiment of an anode for a lithium secondary battery of the present invention, in the concave-convex pattern-formed silicon anode current collector, a metal may be plated over the entire surface of the silicon substrate, except the wall of the convex portion.

According to a particular embodiment of an anode for a lithium secondary battery of the present invention, the metal may be one selected from the group consisting of Pt, Cu and Ni.

According to a particular embodiment of an anode for a lithium secondary battery of the present invention, in the concave-convex pattern-formed silicon anode current collector, impurity may be doped over the entire surface of the silicon substrate, except the wall of the convex portion.

According to a particular embodiment of an anode for a lithium secondary battery of the present invention, the impurity may be boron (B) or phosphorus (P).

According to another aspect of the present invention, there is provided a method for manufacturing an anode for a lithium secondary battery comprising: (a) forming concave-convex patterns on a silicon substrate; (b) plating a metal or doping an impurity on the concave-convex pattern-formed silicon substrate; and (c) depositing a lithium.

According to a particular embodiment of a method for manufacturing an anode for a lithium secondary battery of the present invention, the step (a) may comprise: forming a positive photoresist layer on a silicon substrate by spin coating; placing a photo-mask on the silicon substrate on which the positive photoresist layer is formed and exposing the silicon substrate to UV; partial etching the silicon substrate by a reactive ion etching process; and removing the remaining positive photoresist layer.

According to a particular embodiment of a method for manufacturing an anode for a lithium secondary battery of the present invention, in the step (b), the metal may be plated over the entire surface of the silicon substrate, except the wall of the convex portion of the silicon substrate.

According to a particular embodiment of a method for manufacturing an anode for a lithium secondary battery of the present invention, in the step (b), the metal may be one selected from the group consisting of Pt, Cu and Ni.

According to a particular embodiment of a method for manufacturing an anode for a lithium secondary battery of the present invention, in the step (b), the impurity may be doped over the entire surface of the silicon substrate except the wall of the convex portion of the silicon substrate.

According to a particular embodiment of a method for manufacturing an anode for a lithium secondary battery of the present invention, in the step (b), the impurity may be boron (B) or phosphorus (P).

According to a particular embodiment of a method for manufacturing an anode for a lithium secondary battery of the present invention, in the step (c), the lithium may be formed only on the concave portion of the silicon substrate.

According to another aspect of the present invention, there is provided a lithium secondary battery comprising an anode of any one of claim 1 to claim 6, a cathode; a separator; and an electrolyte.

### Advantageous Effects

A lithium deposited anode for a lithium secondary battery according to the present invention limits dendrite growth only inside the concave portion of the silicon substrate where micro-size concave-convex patterns are formed. It is thus possible to provide a lithium secondary battery having more than 50% improved capacity than that composed of a conventional carbon anode (carbon/LCO battery) by resolving the aforementioned problem of dendrite growth caused from bulk lithium.

### BRIEF DESCRIPTION OF THE DRAWINGS

FIG. 1 is a schematic view illustrating the process of formation of micro-size concave-convex patterns on a silicon substrate.

FIG. 2 is a schematic view illustrating an anode manufactured in Example 1 and a battery structure manufactured in Example 3.

FIG. 3 is a graph illustrating voltage profile and cycle property at 0.5 C-rate of a lithium secondary battery manufactured in Example 3.

FIG. 4 is a graph illustrating cycle property at 0.1 to 1.0 C-rate of a lithium secondary battery manufactured in Example 3.

FIG. 5 is a SEM picture illustrating dendrite growth observed when a bulk lithium anode is used.

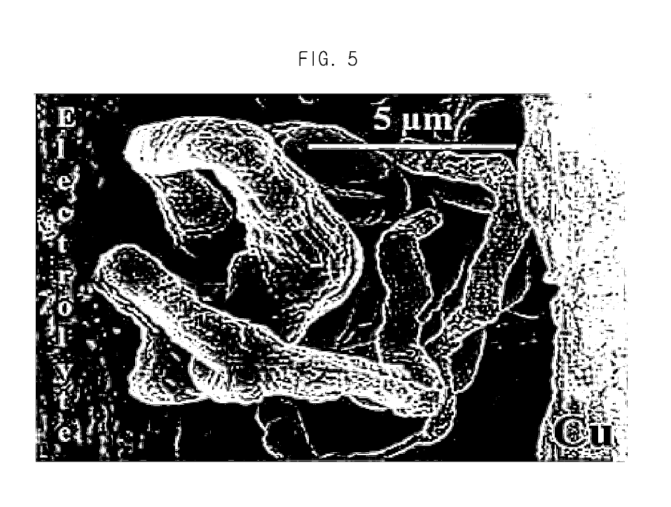

FIGS. 6(a) and (b) are SEM pictures of an anode manufactured in Example 1, FIGS. 6(c) and (d) are SEM pictures of an anode manufactured in Example 1 at 2.0 to 3.6V and 0.5 C-rate after 100 cycles.

### MODE FOR THE INVENTION

While the present invention has been described with reference to particular embodiments, it is to be appreciated that various changes and modifications may be made by those skilled in the art without departing from the spirit and scope of the present invention, as defined by the appended claims and their equivalents. Throughout the description of the present invention, when describing a certain technology is determined to evade the point of the present invention, the pertinent detailed description will be omitted.

The present invention provides an anode for a lithium secondary battery comprising a concave-convex pattern-formed silicon anode current collector and lithium deposited on the concave portion of the silicon anode current collector as an anode active material.

In the concave-convex pattern-formed silicon anode current collector, a metal may be plated or impurity may be doped over the entire surface of the silicon substrate, except the wall of the convex portion. The concave-convex patterns may be formed in micro-size or nano-size. Size of concave-convex patterns may vary with a mask to be used for manufacturing concave-convex patterns. Concave-convex patterns manufactured according to the present invention may be any size in the range of micro-size or may have up to 200 nm of width and up to 700 nm of depth in the range of nano-size.

The metal may be one selected from the group consisting of Pt, Cu and Ni and the impurity may be boron (B) or phosphorus (P). The metal or impurity grants conductivity to the silicon substrate which is a non-conductor at room temperature and prevents reaction to the deposited lithium.

Further, the lithium as the anode active material may be formed only on the concave portion of the silicon substrate. Here, the anode active material means a material releasing electrons to a conducting wire while being oxidized.

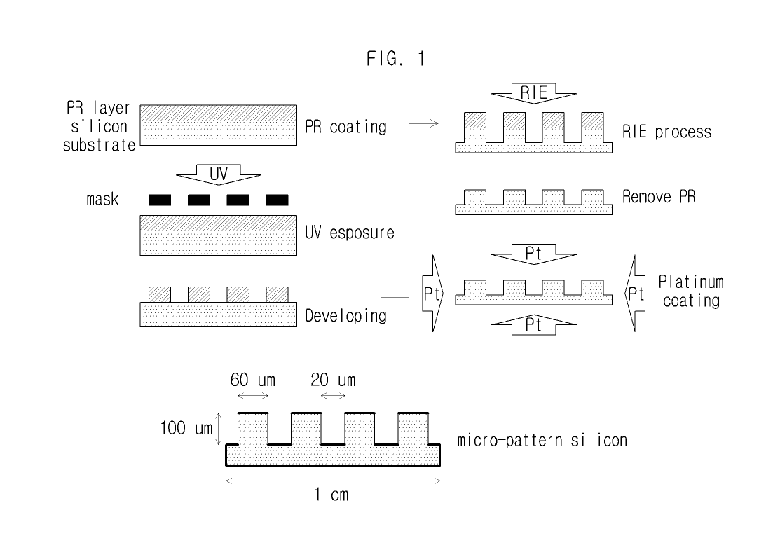

According to a method for manufacturing an anode for a lithium secondary battery of the present invention, concave-convex patterns are formed first on a silicon substrate. FIG. 1 illustrates the process of formation of concave-convex patterns. The concave-convex patterns may be formed in micro-size or nano-size. A method for forming the micro-size concave-convex patterns may include forming a positive photoresist layer on a silicon substrate by spin coating; placing a photo-mask thereon and exposing it to UV, wherein the portion of the photoresist layer where UV is exposed and the portion where UV is not exposed have different dissolution rate to a developing solution so that the portion of the photoresist layer where the photo-mask is not placed is selectively removed; partial etching the silicon substrate by a reactive ion etching process; and removing the remaining positive photoresist layer with a liquid stripping solution. Pure silicon is a non-conductor at room temperature because it has very lower conductivity than a metal.

The micro-size concave-convex patterns-formed silicon substrate is plated with a metal or doped with impurity to provide conductivity and prevent reaction with the lithium to be deposited afterwards. When a metal is plated, it may be one selected from the group consisting of Pt, Cu and Ni. According to a preferred embodiment of the present invention, the metal may be Pt. On the other hand, when impurity is doped, it may be boron (B) or phosphorus (P).

Even though metal plating or impurity doping is performed over the entire surface of the micro-size concave-convex patterns-formed silicon substrate, the metal is not plated or the impurity is not doped on the wall of the convex portion of the silicon substrate. Thus, the deeply caved concave portion of the silicon substrate may be connected with an electrical terminal to be accessed at the bottom but the protruded convex portion of the silicon substrate will be blocked electrically with the bottom thereof.

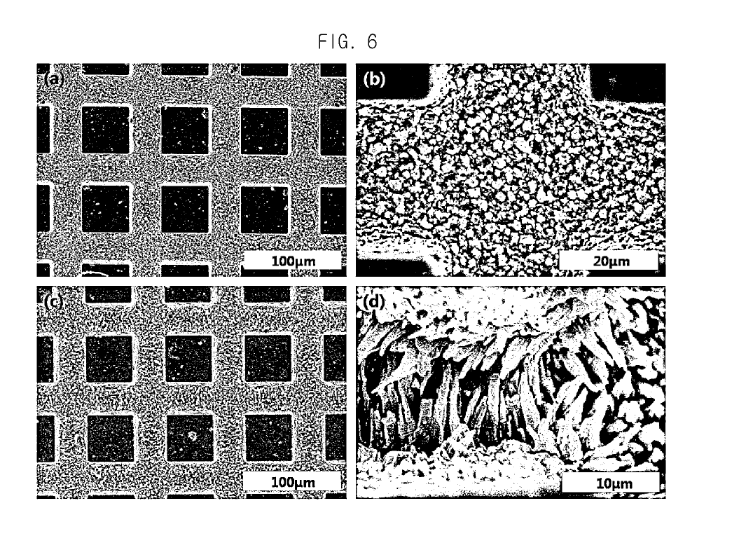

Therefore, when lithium as an anode active material is deposited on the silicon substrate on which the metal is coated except the wall of the convex portion, it will be selectively deposited on the concave portion of the silicon substrate as shown in FIGS. 6(a) and (b).

The present invention further provides a lithium secondary battery comprising the anode manufactured by the above mentioned method; a cathode; a separator; and an electrolyte. According to a preferred embodiment of the present invention, the cathode may be a non-lithium material since lithium is used for the anode. The non-lithium cathode may be one chosen from TiS₂, V₂O₅, V₆O₁₃, NaV₃O₈, ZnV₂O₆, Li₄Ti₅O₁₂, and LiV₃O₈. According to a preferred embodiment of the present invention, the cathode may be LiV₃O₈. Here, Li in Li₄Ti₅O₁₂, and LiV₃O₈ among the non-lithium cathodes does not participate in cell reaction.

During the lithium secondary battery according to the present invention is discharged, lithium deposited only on the concave portion of the silicon substrate may dissolve and during it is charged, lithium deposited only on the concave portion of the silicon substrate may grow. Here, the convex portion of the silicon substrate is blocked electrically since it is not plated with a metal. Thus, it is not involved in charge•discharge cycles but can serve to limit lithium growth only to the concave portion of the micro-size concave-convex patterns-formed silicon substrate, not all over the silicon substrate. Accordingly, a lithium secondary battery manufactured according to the present invention can be one having high capacity and high efficiency by using lithium itself as an anode material and preventing dendrite growth.

Hereinafter, although more detailed descriptions will be given by examples, those are only for explanation and there is no intention to limit the invention.

### Example 1

### Preparation of a Lithium Deposited Anode

A positive photoresist (PR) was coated on the surface of a silicon substrate by employing a spin coating method. A photo-mask was closely placed to the surface of a silicon substrate and then it was exposed under UV. UV exposed PR was dissolved faster in a developing solution than UV unexposed PR. Micro patterns were formed on the surface of a silicon substrate, where the PR was coated, by reactive ion etching process. The remaining PR was then removed using a liquid resist stripping solution. The micro-size concave-convex patterns formed on the silicon substrate had 60 μm of width, 100 μm of depth and 20 μm of distance between convex portions. The concave-convex patterns-formed silicon substrate was cut in 1 cm². Then platinum was coated on the micro-patterned surface of a silicon substrate by employing sputtering method and lithium was electroplated thereon. Here, even though platinum was coated over the entire surface of the silicon substrate, the wall of the protruded convex portion was not coated. Therefore, only deeply caved concave portion was electrically connected with the terminal of an anode which allowed for lithium being deposited only on deeply caved concave portion. Lithium electroplating was performed for 20 hours at a constant current density of 0.45 mA cm⁻² and amount of deposited lithium was about 2.33 mg which was equivalent capacity of 9 mAh.

### Example 2

### Preparation of a Cathode

A cathode was prepared using slurry including 80 wt % lithium trivanadate (LiV₃O₈), denka black as a conductive material and 5 wt % polyvinylidene fluoride (PVDF) as a binder. All materials were dissolved in N-methyl-2-pyrrolidone (NMP) and casted in aluminum foil pieces. LVO was powder having 10 μm of an average particle diameter. The cathode was dried at 120° C. for 1 hour under vacuum. Amount of LVO powder was 3.9 mg and theoretical capacity of the LVO cathode was determined to be about 1.1 mAh.

### Example 3

### Preparation of a Lithium Secondary Battery

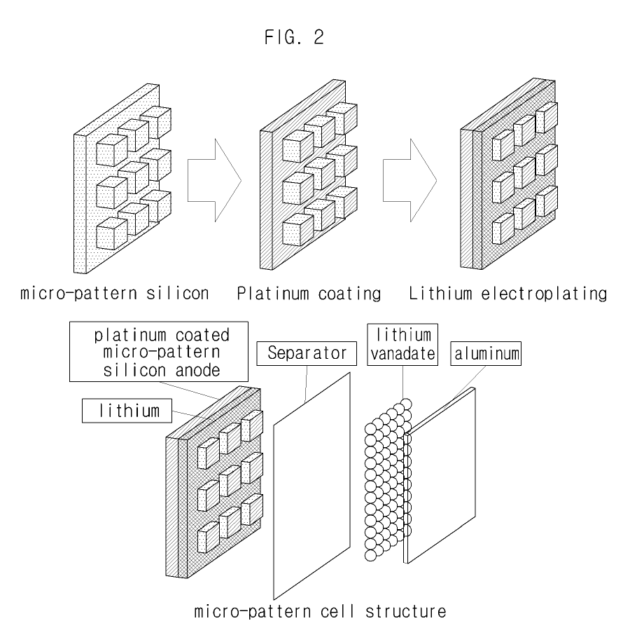

A lithium secondary battery was prepared by using standard coin cell (CR2032) type. An electrolyte was a solution mixed in 1:1:1 volume ratio of ethylene carbonate (EC):dimethyl carbonate (DMC):ethyl methyl carbonate (EMC). Coin cell was prepared in a glove box charged with Ar gas. A micro-size concave-convex patterns-formed silicon anode/LVO cell is shown in FIG. 2.

### Experiment Example 1

### Charge/Discharge Experiment of a Lithium Secondary Battery

The lithium secondary battery prepared in Example 3 was used for charge/discharge experiment under constant current at room temperature (25° C.). Current density was 0.1 to 1.0 C-rate and cut-off voltage was in the range of 2.0 to 3.6V. Electrochemical behavior of the cell in Wonatech 300 cycler was determined with SEM (Hitachi, S-4700).

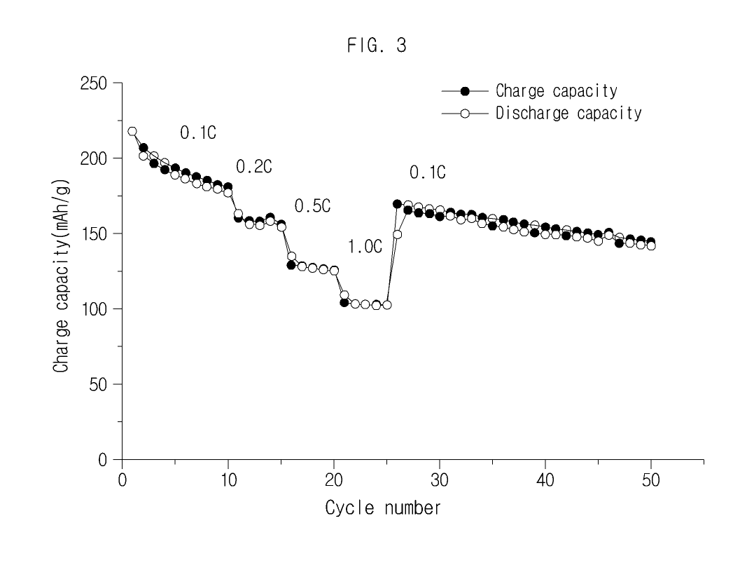

The lithium secondary battery showed 218.0 mAhg⁻¹ of charge capacity which was close to the theoretical capacity and 99.9% of coulombic efficiency at 0.1 C-rate. Discharge capacity of the lithium secondary battery after 1 cycle was 143 mAhg⁻¹ at 0.5 C-rate and was decreased gradually up to 106 mAhg⁻¹ after 100 cycles, in which the initial discharge capacity was found to be 74.1%. As shown in FIG. 3, this cycle data shows that the inhibition of dendrite growth of lithium is stable due to micro-patterned silicon.

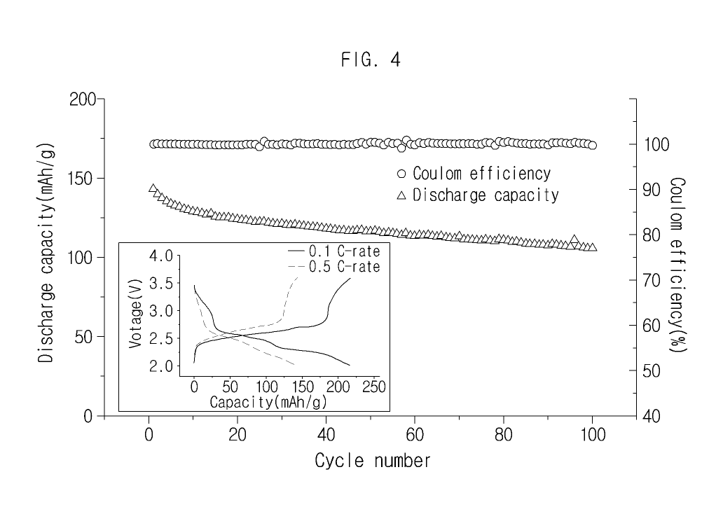

As shown in FIG. 4, it is noted that discharge capacity decreases with increasing current rate. When the capacity at 0.1 C-rate is compared to that at 1.0 C-rate, it is noted that about 50% of capacity is decreased. This may be overcome by increasing electrical conductivity by adding additives into the LVO since it is caused by characteristics of LVO. Important point to note here is that it lasts more than 100 charge/discharge cycles, which means that dendrite growth is prevented even though the lithium anode of the present invention is used. When the SEM picture of the charged anode in FIGS. 6 (c) and (d), taken after the cell prepared in Example 3 was performed for 100 charge/discharge cycles, was compared to that of an anode of the cell in FIGS. 6 (a) and (b) taken before performing charge/discharge experiment, it is noted that the protruded convex portion has no changes and lithium has grown only at the deeply caved concave portion. It is also noted that lithium has grown in the shape of small piece of wood at the charged anode after 100 charge/discharge cycles and dendrite growth is shown only inside the deeply caved concave portion.

Therefore, the lithium deposited anode for a lithium secondary battery of the present invention may resolve the problems of the dendrite growth associated with the conventional lithium secondary battery using carbon anode (carbon/LCO battery) by limiting dendrite growth only inside the concave portion of the silicon substrate, resulting in more than 50% of increased capacity. In addition, a manufacturing process may be simplified by including the method for manufacturing an anode for a lithium secondary battery of the present invention into the existing semiconductor process.

While it has been described with reference to particular embodiments, it is to be appreciated that various changes and modifications may be made by those skilled in the art without departing from the spirit and scope of the embodiment herein, as defined by the appended claims and their equivalents.

1. An anode for a lithium secondary battery comprising a concave-convex pattern-formed silicon anode current collector and lithium deposited on the concave portion of the silicon anode current collector as an anode active material.

2. The anode for a lithium secondary battery of claim 1, wherein in the concave-convex pattern-formed silicon anode current collector, a metal is plated over the entire surface of the silicon substrate, except the wall of the convex portion.

3. The anode for a lithium secondary battery of claim 2, wherein the metal is one selected from the group consisting of Pt, Cu and Ni.

4. The anode for a lithium secondary battery of claim 1, wherein in the concave-convex pattern-formed silicon anode current collector, an impurity is doped over the entire surface of the silicon substrate, except the wall of the convex portion.

5. The anode for a lithium secondary battery of claim 4, wherein the impurity is boron (B) or phosphorus (P).

6. A method for manufacturing an anode for a lithium secondary battery comprising:
(a) forming concave-convex patterns on a silicon substrate;
(b) plating a metal or doping impurity on the concave-convex pattern-formed silicon substrate; and
(c) depositing a lithium.

7. The method of claim 6, wherein the step (a) comprises:
Forming a positive photoresist layer on a silicon substrate by spin coating;
placing a photo-mask on the silicon substrate on which the positive photoresist layer is formed and exposing it to UV;
partial etching the silicon substrate by a reactive ion etching process; and
removing the remaining positive photoresist layer.

8. The method of claim 6, wherein in the step (b), the metal is plated over the entire surface of the silicon substrate, except the wall of the convex portion of the silicon substrate.

9. The method of claim 8, wherein the metal is one selected from the group consisting of Pt, Cu and Ni.

10. The method of claim 6, wherein in the step (b), the impurity is doped over the entire surface of the silicon substrate except the wall of the convex portion of the silicon substrate.

11. The method of claim 10, wherein the impurity is boron (B) or phosphorus (P).

12. The method of claim 6, wherein in the step (c), the lithium is formed only on the concave portion of the silicon substrate.

13. A lithium secondary battery comprising an anode of claim 1, a cathode; a separator; and an electrolyte.
